(19) United States
(12) Patent Application Publication
(10) Pub. No.: US 2014/0024213 A1
(43) Pub. Date: Jan. 23, 2014

(54) PROCESSES FOR FORMING INTEGRATED CIRCUITS WITH POST-PATTERNING TREAMENT

(71) Applicants: Bernd Hintze, Langebruck (DE); Frank Koschinsky, Radebeul (DE); Uwe Stoeckgen, Dresden (DE)

(72) Inventors: Bernd Hintze, Langebruck (DE); Frank Koschinsky, Radebeul (DE); Uwe Stoeckgen, Dresden (DE)

(73) Assignee: GLOBALFOUNDRIES Inc., Grand Cayman (KY)

(21) Appl. No.: 13/551,872

(22) Filed: Jul. 18, 2012

(51) Int. Cl. H01L 21/768; H01L 21/308

(52) U.S. Cl. 438/653; 438/675; 438/702; 257/E21.586; 257/E21.231; 257/E21.584

(57) ABSTRACT

Processes for forming an integrated circuit are provided. In an embodiment, a process for forming an integrated circuit includes forming a low-k dielectric layer overlying a base substrate. An etch mask is patterned over the low-k dielectric layer. A recess is etched into the low-k dielectric layer through the etch mask to expose a recess surface within the recess. The low-k dielectric layer and the base substrate are annealed after etching. Annealing is conducted in an annealing environment, such as in an annealing furnace that provides the annealing environment. The recess surface is exposed to the annealing environment. An electrically-conductive material is deposited in the recess after annealing to form an embedded electrical interconnect.

### TECHNICAL FIELD

The present invention generally relates to processes for forming integrated circuits, and more particularly relates to techniques for treating recess surfaces in recesses, such as trenches and/or vias, after recess formation.

### BACKGROUND

Integrated circuits have been pivotal to accelerating progress in electronic device performance, enabling device sizes to shrink without sacrificing performance. Integrated circuits have been widely adopted for electronic devices, as opposed to designs using discrete transistors, due to various capabilities that are enabled by the integrated circuits. For example, integrated circuits can be readily mass produced, generally exhibit excellent reliability, and enable a building-block approach to circuit design.

Integrated circuits generally include a semiconductor substrate including a device, such as a transistor, disposed therein. In fact, modern integrated circuits may contain millions of transistors disposed therein. Layers of dielectric materials are formed over the semiconductor substrates. Additionally, electrical connections between the devices in the integrated circuit are formed in the layers of dielectric materials. In particular, numerous levels of interconnect routing in the form of embedded electrical interconnects, such as copper lines and dots, are generally embedded within the layers of dielectric material to connect the devices within the integrated circuits. Each level of interconnect routing is separated from immediately adjacent levels by the dielectric material, referred to in the art as an interlayer dielectric (ILD). Adjacent levels of interconnect routing may be embedded in distinct layers of ILD, and with the interconnect routing configured in such a way so as to ensure that dielectric material separates the adjacent interconnect routings.

To selectively connect adjacent levels of interconnect routing, and also to form other structures in the integrated circuits, successive patterning techniques are generally employed by which a layer of dielectric material is formed overlying a base substrate, which may be a layer of dielectric material including an adjacent level of interconnect routing or may be the semiconductor substrate including electrical contacts for the devices therein. An etch mask is then formed and patterned over the layer of dielectric material, with patterned gaps in the etch mask selectively exposing a surface of the layer of dielectric material. Recesses are then etched into the layer of dielectric material through the patterned gaps in the etch mask, with multiple cycles of masking and etching conducted depending upon the number and type of dielectric layers to be etched through and further depending upon a desired configuration of vias and trenches in the layer of dielectric material. As a result of etching, a surface of the interconnect routing or electrical contact in the underlying substrate can be exposed in the vias. Etch masks are then removed and material is deposited in the vias and trenches, such as electrically-conductive material or other types of depositable material, to form embedded features within the layer of dielectric material. When the deposited material is electrically-conductive, the embedded features formed in the vias and trenches may represent a new level of interconnect routing, and may further serve to interconnect the adjacent levels of interconnect routing or electrical contacts in the underlying substrate. The patterning technique may be repeated in subsequently-formed layers of dielectric materials.

Despite the ability to mass produce integrated circuits, minor defects within integrated circuits can result in device inoperability or inefficiency. For example, although modern patterning techniques are robust, the patterning techniques may result in damage to certain dielectric materials, such as porous low-k or ultra low-k dielectric layers. The patterning techniques may also result in formation of impurities within the trenches and/or vias. For example, etch residue may remain in trenches as a result of etch patterning techniques, and/or may result in oxide formation on exposed electrically-conductive surfaces within the vias. Prolonged environmental exposure of exposed electrically-conductive surfaces in the vias may also result in oxide formation. The impurities in the trenches and/or vias impact formation of subsequent features in the trenches and/or vias.

Post-patterning treatments, such as hydrogen, helium, amine, and methane plasma etching techniques, have been investigated to remove impurities that are formed as a result of patterning techniques. However, such post-patterning treatments may still negatively impact certain low-k and ultra low-k dielectric materials by increasing the k value of the dielectric materials. For example, when certain low-k and ultra low-k dielectric materials, such as carbon-doped silicon oxide (SiOCH), are exposed to post-patterning plasma etching, carbon may be depleted therefrom, thereby resulting in an unwanted increase in k value of the dielectric materials.

Accordingly, it is desirable to provide processes for forming integrated circuits that employ alternative post-patterning treatments for removing impurities that are formed as a result of patterning techniques, or that otherwise remedy damage that is caused to the dielectric materials during patterning, while minimizing negative impacts on dielectric materials that are caused by existing post-patterning treatments that involve use of plasmas. Furthermore, other desirable features and characteristics of the present invention will become apparent from the subsequent detailed description of the invention and the appended claims, taken in conjunction with the accompanying drawings and this background of the invention.

### BRIEF SUMMARY

Processes for forming an integrated circuit are provided. In an embodiment, a process for forming an integrated circuit includes forming a low-k dielectric layer overlying a base substrate. An etch mask is patterned over the low-k dielectric layer. A recess is etched into the low-k dielectric layer through the etch mask to expose a recess surface within the recess. The low-k dielectric layer and the base substrate are annealed after etching. Annealing is conducted in an annealing environment free from plasma, and the annealing environment has a temperature of at least about 100° C. The recess surface is exposed to the annealing environment. An electrically-conductive material is deposited in the recess after annealing to form an embedded electrical interconnect.

In another embodiment, a process for forming an integrated circuit includes forming a low-k dielectric layer overlying a base substrate. An etch mask is patterned over the low-k dielectric layer. A recess is etched into the low-k dielectric layer through the etch mask to expose a recess surface within the recess. The base substrate having the low-k dielectric layer thereon is introduced into an annealing furnace after etching the recess. The annealing furnace provides an annealing environment. The recess surface is exposed to the annealing environment. An electrically-conductive material is deposited in the recess after annealing to form an embedded electrical interconnect.

In another embodiment, a process for forming an integrated circuit includes forming a dielectric layer overlying a base substrate. An etch mask is patterned over the dielectric layer. A recess is etched into the dielectric layer through the etch mask to expose a recess surface within the recess. The base substrate having the dielectric layer thereon is introduced into an annealing furnace after etching the recess. The annealing furnace provides an annealing environment. The recess surface is exposed to the annealing environment. At least one overlying layer is formed over the dielectric layer after annealing. Portions of the at least one overlying layer are removed from a surface of the dielectric layer outside of the recess to form an embedded feature within the recess.

### BRIEF DESCRIPTION OF THE DRAWINGS

The present invention will hereinafter be described in conjunction with the following drawing figures, wherein like numerals denote like elements, and wherein:

FIG. 1 is a schematic cross-sectional side view of a dielectric layer formed on a base substrate;

FIG. 2 is a schematic cross-sectional side view of an etch mask patterned over the dielectric layer of FIG. 1, with the etch mask having two patterned gaps and with recesses etched in the dielectric layer through the patterned gaps in the etch mask in accordance with an embodiment;

FIG. 3 is a schematic cross-sectional side view of the base substrate having the dielectric layer thereon, as shown in FIG. 2, introduced into an annealing furnace in accordance with an embodiment;

FIG. 4 is a schematic cross-sectional side view of the base substrate having the dielectric layer thereon, as shown in FIG. 3, with the recesses filled with electrically-conductive material to form embedded electrical interconnects;

FIG. 5 is a schematic cross-sectional side view of the base substrate having the dielectric layer thereon, as shown in FIG. 4, with capping layers formed over the dielectric layer and the embedded electrical interconnects;

FIG. 6 is a schematic cross-sectional side view of an etch mask patterned over the dielectric layer of FIG. 1, with the etch mask having two patterned gaps and with recesses etched in the dielectric layer through the patterned gaps in the etch mask in accordance with another embodiment;

FIG. 7 is a schematic cross-sectional side view of the base substrate having the dielectric layer thereon, as shown in FIG. 6, introduced into an annealing furnace in accordance with an embodiment; and

FIG. 8 is a schematic cross-sectional side view of an embodiment of an integrated circuit prepared in accordance with an embodiment.

### DETAILED DESCRIPTION

The following detailed description is merely exemplary in nature and is not intended to limit the invention or the application and uses of the invention. Furthermore, there is no intention to be bound by any theory presented in the preceding background or the following detailed description.

Processes for forming integrated circuits are provided herein. The processes include patterning and etching of recesses in a dielectric layer that overlies a base substrate during formation of integrated circuits, and further include introducing the base substrate having the dielectric layer thereon into an annealing environment, such as an annealing environment that is provided by an annealing furnace, after etching the recess. Recess surfaces are exposed to the annealing environment, and annealing that is conducted in the annealing environment remediates damage and/or impurity formation in the recesses as a result of patterning and etching. By remediating damage and/or impurity formation in the recesses, conformal formation of overlying layers on the dielectric layer in the recess is enhanced, thereby enabling resistive-capacitive (RC) delay and time-dependent gate oxide breakdown (TDDB) to be minimized, while also minimizing impact to a k value of the dielectric layer within which the recesses are formed.

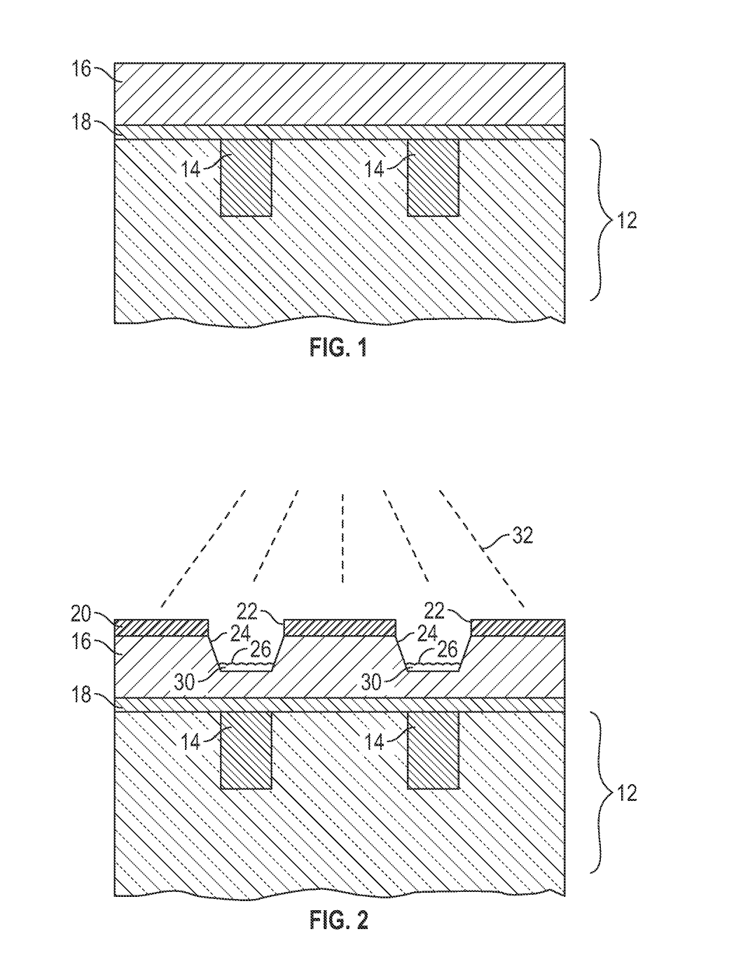

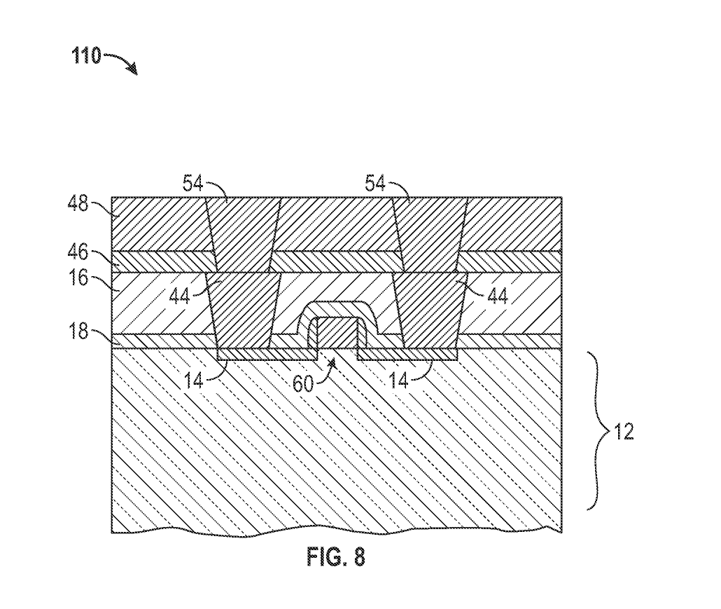

An exemplary embodiment of a process for forming an integrated circuit 10 will now be addressed with reference to FIGS. 1-5. Referring to FIG. 1, a base substrate 12 is provided, over which a dielectric layer 16 is formed as described in further detail below. The base substrate 12 is not particularly limited and can be any substrate over which the dielectric layer 16 is formed. As shown in FIG. 1, the base substrate 12 may include at least one embedded electrical contact 14 and, although not shown, may include millions of embedded electrical contacts 14 that are disposed in the base substrate 12. In this regard, the embedded electrical contacts 14 may be formed with nanometer-scale dimensions, e.g., with tolerances of less than 1×10⁻⁶ mm and feature sizes of less than 1 mm. The base substrate 12 may be an underlying dielectric substrate including the at least one embedded electrical contact 14 disposed therein, as shown in FIG. 1. Alternatively, as shown in FIG. 8, the base substrate 12 may be an underlying semiconductor substrate that includes a device 60, such as a transistor, capacitor, resistor, or the like, with the at least one embedded electrical contact 14 being in electrical communication with the device 60. Further, the base substrate 12 may include a plurality of the devices 60, and the processes described herein may be applicable to wafer level packaging as well as die level packaging. Alternatively still, the base substrate 12 may be free of embedded electrical contacts 14 disposed therein and may be any substrate upon which layers of dielectric material may be formed.

As alluded to above and as also shown in FIG. 1, the dielectric layer 16 is formed overlying the base substrate 12. The dielectric layer 16 includes a first dielectric material. In an embodiment, the first dielectric material may be a low k or ultra-low k material. As referred to herein, “low k” material also encompasses ultra low-k, extremely low-k, or any other low-k material as understood in the art, which materials are particularly useful in dielectric layers of integrated circuits. In an embodiment, the low-k dielectric layer 16 includes an oxide such as, for example, a silicon oxide. In a further embodiment, the low-k dielectric layer 16 is a porous low-k dielectric layer 16. For example, the porous low-k dielectric layer 16 can include carbon-doped silicon oxide. The processes described herein may be particularly applicable for carbon-doped silicon oxide dielectric layers 16 because carbon depletion from the dielectric layer 16 is a concern with existing techniques that are employed to remediate impurity formation in recesses and because carbon depletion of the carbon-doped silicon oxide dielectric layer 16 can be substantially avoided in the processes described herein.

In an embodiment, although not shown, the dielectric layer 16 may be disposed directly upon a surface of the base substrate 12. In another embodiment, as shown in FIG. 1, at least one underlying dielectric layer 18 is formed over the base substrate 12 prior to forming the dielectric layer 16 overlying the base substrate 12. The at least one underlying dielectric layer 18 may be an etch-stop layer that resists etching so as to prevent etching of the dielectric layer 16 from promulgating to underlying layers. In this regard, the at least one underlying dielectric layer 18 may be formed from a different dielectric material from the first dielectric material, such as a silicon nitride or silicon carbide under circumstances where the first dielectric material is a silicon oxide. Silicon nitride or silicon carbide may be deposited through plasma-enhanced chemical vapor deposition (PECVD). Alternatively, although not shown, the at least one underlying dielectric layer may include another level of interlayer dielectric layers that include interconnect routing. Although not shown in FIG. 1, at least one overlying dielectric layer, such as a TEOS layer, may be formed over the dielectric layer 16 after forming the dielectric layer 16 and prior to subsequent patterning as described in further detail below. The at least one overlying dielectric layer may be formed through conventional techniques such as chemical vapor deposition (CVD). Configurations of layers as described above, including the etch-stop layer 18, dielectric layer 16 as described herein, and TEOS layer, are well known in the art of integrated circuit design.

The exemplary process continues with etching a recess 24 into the dielectric layer 16, as shown in FIG. 2. Referring to FIG. 2, a lithography process is employed to etch the recess 24 into the dielectric layer 16 which, in the embodiment of FIG. 2, is a trench 24. In particular, as shown in FIG. 2, an etch mask 20 is patterned over the dielectric layer 16, with the etch mask 20 having at least one patterned gap 22 that selectively exposes a surface of the dielectric layer 16 for enabling the dielectric layer 16 to be etched through the at least one patterned gap 22 with an appropriate etchant 32. It is to be appreciated that the etch mask 20 may have millions of patterned gaps 22 therein. Like the embedded electrical contacts 14 that may be disposed in the base substrate 12, the patterned gaps 22 may be formed with nanometer-scale dimensions. The at least one patterned gap 22 in the etch mask 20 may be configured in any pattern based upon a configuration of recesses that are to be etched in the dielectric layer 16 through the patterned gaps 22. The etch mask 20 may be formed through conventional lithography techniques, such as by negative or positive photolithography. Although the etch mask 20 may be disposed directly upon the dielectric layer 16, it is to be appreciated that the at least one overlying dielectric layer may be disposed between the etch mask 20 and the dielectric layer 16.

The recess 24 is then etched into the dielectric layer 16 through the etch mask 20, in particular through the at least one patterned gap 22 in the etch mask 20, to expose a recess surface 26 within the recess 24. As referred to herein, the recess surface 26 is any surface that is exposed in the recess 24 as a result of etching. As shown in the embodiment of FIG. 2, the recess surface 26 is contained within the dielectric layer 16; however, it is to be appreciated that in other embodiments, the recess surface 26 may extend across multiple dielectric layers in the recess 24 when the recess 24 is etched through multiple dielectric layers. It is to be appreciated that multiple cycles of etching may be conducted depending upon the number and type of layers to be etched through to form the recess 24. In the embodiment shown in FIG. 2, etching the recess 24 includes etching a trench 24 into the dielectric layer 16 (in particular, FIG. 2 shows two trenches 24 etched into the dielectric layer 16), and the dielectric layer 16 is the only layer into which the recesses are etched. Etching may be conducted with an appropriate etching technique using an appropriate etchant 32 based upon the particular first dielectric material (or materials of other layers that are optionally disposed under the etch mask 20 and that are to be etched through). For example, when the first dielectric material is an oxide such as carbon-doped silicon oxide, an oxide etchant 32 may be employed. Examples of suitable oxide etchants 32 include, but are not limited to, CHF₃, CF₄, or SF₆. Although particular etching techniques are not limited, the recess 24 may be etched through dry etching techniques, also referred to in the art as plasma etching techniques.

In an embodiment and as shown in FIG. 2, where the recess 24 is shown as the trench 24 in the dielectric layer 16, the recess surface 26 is shown to include etch residue 30 as a result of etching. The etch residue 30 has a different chemical composition than the dielectric layer 16, and may be of a polymeric nature. The presence of the etch residue 30 may result in uneven topography of the recess surface 26, thereby impacting formation of subsequent features in the recess 24 by creating gaps. Although the etch residue 30 is often present as a result of etching, the presence of etch residue 30 in the recess surface 26 is not required in accordance with the processes described herein, and the presence or absence of the etch residue 30 in the recess surface 26 does not modify the processes as described herein.

After etching the recess 24 into the dielectric layer 16, the exemplary process continues with introducing the base substrate 12 having the dielectric layer 16 thereon into an annealing environment 34, with the recess surface 26 exposed to the annealing environment 34. By exposing the recess surface 26 to the annealing environment 34, any etch residue 30 that is present in the recess surface 26 may be effectively removed, thereby avoiding any impact on contact resistance that may result from the presence of the etch residue 30. Further, in circumstances in which the dielectric layer 16 includes porous low-k dielectric material such as carbon-doped silicon oxide, removal of the etch residue 30 may reverse a decrease in porosity of the dielectric layer 16 that occurs due to the presence of the etch residue 30. However, it is to be appreciated that the presence of etch residue 30 in the recess surface 26 is not a pre-requisite to introducing the base substrate 12 having the dielectric layer 16 thereon into the annealing environment 34. For example, introducing the base substrate 12 having the dielectric layer 16 thereon into the annealing environment 34, with the recess surface 26 exposed to the annealing environment 34, may be effective to reduce moisture on the recess surface 26 under circumstances where an etch clean may introduce moisture on the recess surface 26 or where long wait times between fabrication stages may result in uptake of moisture by the recess surface 26.

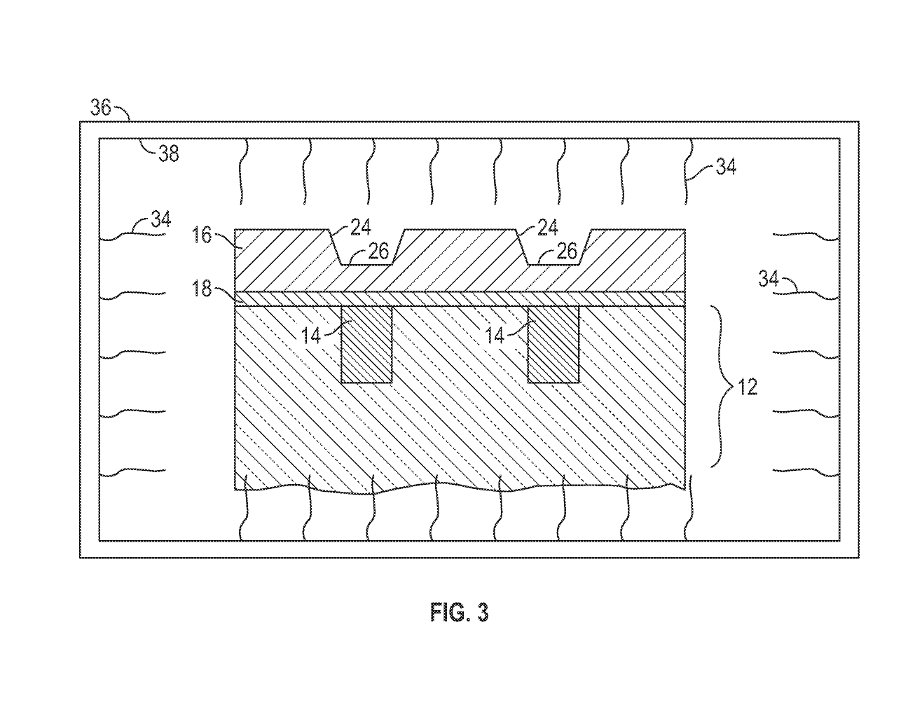

By an “annealing environment”, it is meant an environment that is at an elevated temperature, optionally in the presence of an inert gas and/or a reducing gas. In an embodiment, the annealing environment 34 has a temperature of at least about 100° C., such as from about 100 to about 400° C., or such as from about 250 to about 350° C., or such as from about 300 to about 350° C. In a further embodiment, the annealing environment 34 is free from plasma, i.e., free from ionized gases. As an example, in an embodiment and as shown in FIG. 3, the dielectric layer 16 is introduced into an annealing furnace 36, and the annealing furnace 36 provides the annealing environment 34. As described herein, the “annealing furnace” refers to a component having an internal, isolated chamber 38 into and out of which the base substrate 12 having the dielectric layer 16 thereon can be transported, with at least some structure (such as a curtain, door, lid, wall, or the like) separating the isolated chamber 38 from an ambient environment. The annealing furnace 36 may be dedicated to only conduct annealing, or may be integrated into a single wafer chamber within which multiple fabrication techniques are conducted, although higher throughput may be possible and contamination may be easier to avoid by employing the annealing furnace 36 dedicated only to conduct annealing. The annealing environment 34 provided by the annealing furnace 36 is generally stable and flexible in regards to temperature, temperature ramp, pressure, and pressure ramp. In this manner the annealing environment 34 provided by the annealing furnace 36 is easily controlled, which is ideal for sensitive operations associated with forming integrated circuits. Annealing furnaces 36 also provide substantially homogeneous temperature distribution over the entire substrate, which may be an entire semiconductor wafer, as opposed to local annealing that may be performed at a device level. It is to be appreciated that the annealing environment 34 is not necessarily limited to one that is provided by the annealing furnace 36 as described herein. For example, although not shown, the base substrate 12 having the dielectric layer 16 thereon may be annealed with a localized heating source that provides the annealing environment 34 having a temperature of at least about 100° C. in the absence of plasma, but with no physical separation between the annealing environment 34 and an ambient environment. Pressure of the annealing environment 34 is not particularly limited.

It is to be appreciated that residence time of the base substrate 12 having the dielectric layer 16 thereon in the annealing environment 34 is not particularly limited and that any length of time in the annealing environment 34 is effective for removing at least some etch residue 30. In an embodiment, residence time of the base substrate 12 in the annealing environment 34 is from about 2 minutes to about 2 hours, such as about 25 minutes.

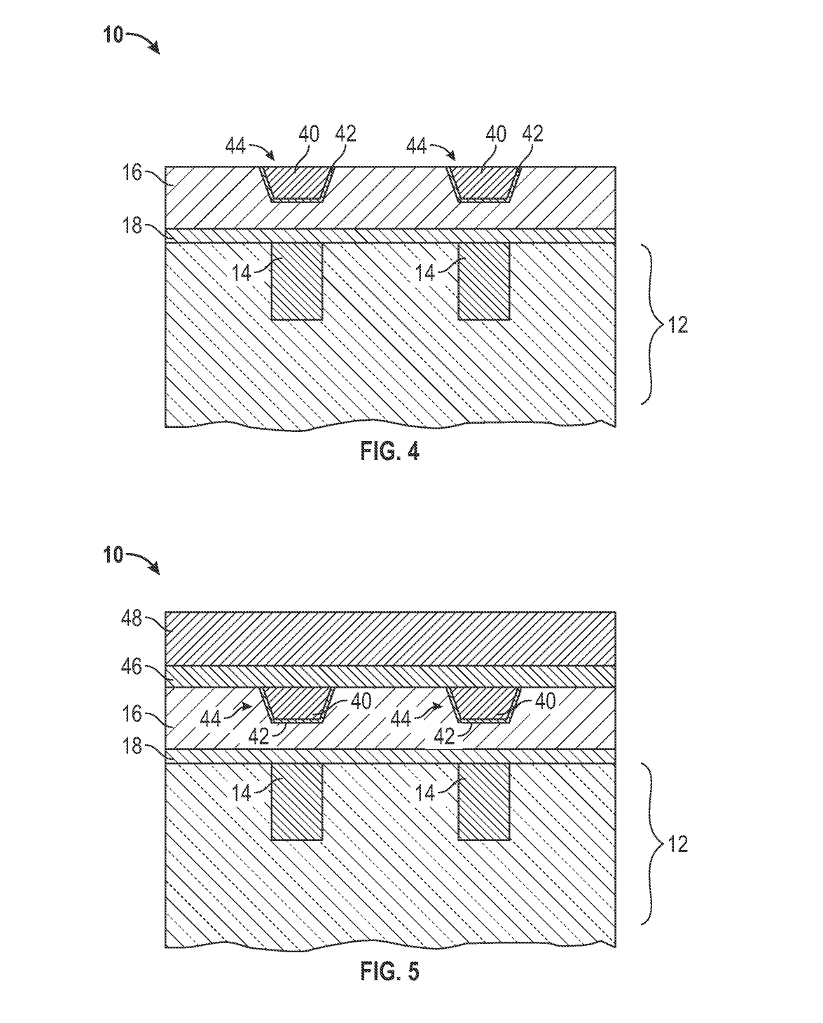

After introducing the base substrate 12 having the dielectric layer 16 thereon into the annealing environment 34, the recess 24 is filled with an overlying material. For example, in an embodiment and as shown in FIG. 4, at least one overlying layer 40, 42 is formed over the dielectric layer 16, including in the recess 24, followed by removing portions of the at least one overlying layer 40, 42 from a surface of the dielectric layer 16 outside of the recess 24, such as through chemical mechanical planarization (CMP) to form an embedded feature 44 within the recess 24. The overlying material is not particularly limited, and multiple overlying layers 40, 42 can be formed. For example, in an embodiment, one overlying layer 40 includes electrically-conductive material and the electrically-conductive material is deposited in the recess 24 after annealing to form the embedded feature 44 as an embedded electrical interconnect 44. The electrically-conductive material is not particularly limited and can be a metal such as copper, tungsten, titanium, or combinations thereof. However, it is to be appreciated that other electrically-conductive materials that are known for use in integrated circuits, such as titanium nitride, can also be used. Optionally, and as shown in FIG. 4, another overlying layer 42 includes a barrier material that is different from the electrically-conductive material such as, but not limited to, tantalum and/or tantalum nitride, and the barrier material is deposited in the recess 24 after annealing and prior to depositing the electrically-conductive material in the recess 24 to form the other overlying layer 42 as a barrier layer 42 in the recess 24. When the barrier layer 42 is present, the electrically-conductive material is deposited over the barrier layer 42 in the recess 24 to form the embedded electrical interconnect 44.

After forming the embedded electrical interconnect 44, additional layers may be formed over the dielectric layer 16 and the embedded electrical interconnect 44. For example, in an embodiment and as shown in FIG. 5, capping layers 46 and 48 are formed over the embedded electrical interconnect 44 and the barrier layer 42 to further form the integrated circuit 10 consistent with fabrication of integrated circuits.

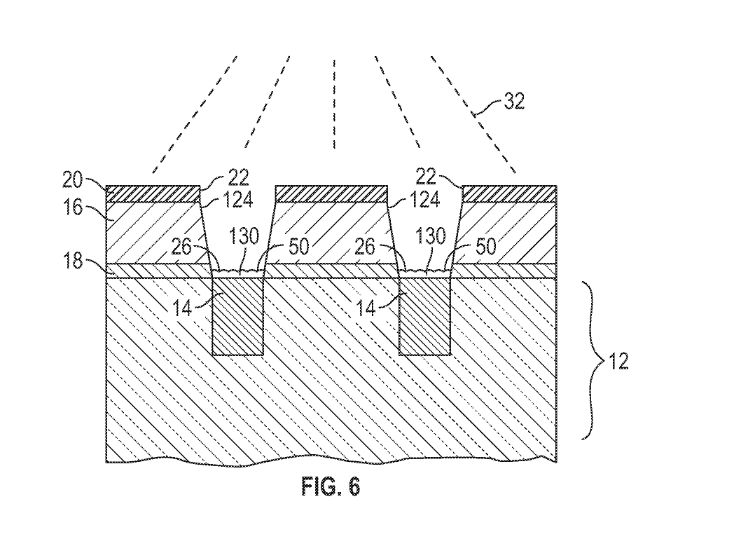

Another exemplary embodiment of a process for forming an integrated circuit 110 will now be addressed with reference to FIGS. 1 and 6-8. The process of this embodiment includes forming the dielectric layer 16 overlying the base substrate 12 in the same manner as described above and as shown in FIG. 1. Patterning of the etch mask 20 and etching is also conducted in the same manner as described above, but in this embodiment, etching the recess 124 includes etching a via 124 through the dielectric layer 16. As shown in FIG. 6, the base substrate 12 includes the embedded electrical contact 14 disposed therein, and the via 124 is etched through the low-k dielectric layer 16 over the embedded electrical contact 14 that is disposed in the base substrate 12 to expose a surface 50 of the embedded electrical contact 14 in the via 124 as a portion of the recess surface 26. It is to be appreciated that this embodiment illustrates etching of the via 124, as opposed to etching of the trench 24 as described above in another exemplary embodiment of the process, for purposes of describing unique challenges for via etching versus trench etching. It is also to be appreciated that, in practice, a combination of trenches 24 and vias 124 can be etched in or through the dielectric layer 16, respectively, and techniques for patterning and etching the trenches 24 and vias 124 may be conducted concurrently or in separate stages.

In an embodiment and as shown in FIG. 6, where the recess 24 is shown as the via 124 through the dielectric layer 16, the recess surface 26, in particular the surface 50 of the embedded electrical contact 14 that is exposed in the recess 24 as part of the recess surface 26, is shown to include residue 130. The residue 130 may include etch residue that is present as a result of etching and that is described above. Alternatively or in addition to etch residue, the residue 130 illustrated in this embodiment may include metal oxide that forms as a result of environmental exposure of the surface 50 of the embedded electrical contact 14. The presence of the residue 130 in the surface 50 of the embedded electrical contact 14 may result in uneven topography of the recess surface 26, and, when the residue 130 includes metal oxide, may further result in higher resistivity as compared to conditions in which the metal oxide is absent from the surface 50 of the embedded electrical contact 14. Metal oxide formation as a result of environmental exposure is associated with long queue times that may occur during different fabrication stages when the surface 50 of the embedded electrical contact 14 is exposed. Introduction of the base substrate 12 having the dielectric layer 16 thereon into the annealing environment 34 provides queue time flexibility since the impact of long queue times can be reversed by introducing the base substrate 12 having the dielectric layer 16 thereon into the annealing environment 34 shortly before further processing.

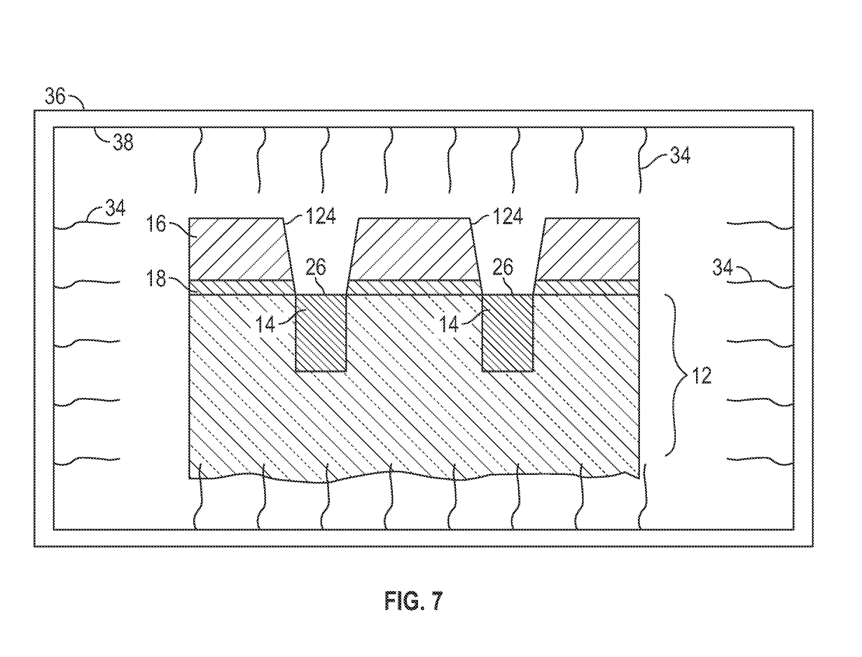

The base substrate 12 having the dielectric layer 16 thereon may be introduced into the annealing environment 34 in the same manner as described above, and as shown in FIG. 7. However, in this embodiment, the presence of reducing gas in the annealing environment 34 may assist with removal of metal oxides from the recess surface 26. Suitable reducing gases include, but are not limited to, hydrogen; ammonia; and hydrocarbon gases including methane and other gases having the general formula CxHy. When the dielectric layer 16 includes carbon-doped silicon oxide, it is to be appreciated that residence times, temperatures, and gas compositions can be modified to maximize removal of metal oxides while minimizing potential carbon depletion from the carbon-doped silicon oxide. FIG. 8 illustrates an integrated circuit 110 in accordance with this embodiment, after filling the recess 24 with an overlying material and after forming the capping layers 46, 48 over the dielectric layer 16 and the embedded electrical interconnect 44 in the same manner as described above. FIG. 8 also illustrates a device 60, such as a transistor, in the base substrate 12, with the embedded electrical contacts 14 in the base substrate 12 being associated with the transistor. Additional embedded interconnects 54, as shown in FIG. 8, may be formed in the capping layers 46, 48 in the same manner as the embedded electrical interconnects 44 are formed.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention. It being understood that various changes may be made in the function and arrangement of elements described in an exemplary embodiment without departing from the scope of the invention as set forth in the appended claims.

1. A process for forming an integrated circuit, said process comprising:
forming a low-k dielectric layer overlying a base substrate;
patterning an etch mask over the low-k dielectric layer;
etching a recess into the low-k dielectric layer through the etch mask to expose a recess surface within the recess;
annealing the low-k dielectric layer and the base substrate after etching, wherein annealing is conducted in an annealing environment free from plasma and having a temperature of at least about 100° C. with the recess surface exposed to the annealing environment; and
depositing an electrically-conductive material in the recess after annealing to form an embedded electrical interconnect.

2. The process of claim 1, wherein annealing is conducted in an annealing furnace that provides the annealing environment.

3. The process of claim 2, further comprising introducing the base substrate having the low-k dielectric layer thereon into the annealing furnace after etching the recess.

4. The process of claim 1, wherein the annealing environment comprises a gas chosen from inert gas or reducing gas and wherein annealing is conducted in the annealing environment comprising the gas.

5. The process of claim 1, wherein the low-k dielectric layer comprises a porous low-k dielectric layer, and wherein the recess is etched into the porous low-k dielectric layer.

6. The process of claim 5, wherein the porous low-k dielectric layer comprises a carbon-doped silicon oxide, and wherein the recess is etched into the carbon-doped silicon oxide layer.

7. The process of claim 1, further comprising forming at least one underlying dielectric layer over the base substrate prior to forming the low-k dielectric layer.

8. The process of claim 1, wherein etching the recess comprises etching a trench into the low-k dielectric layer and/or a via extending through the low-k dielectric layer.

9. The process of claim 8, wherein etching the recess comprises etching the trench into the low-k dielectric layer with the recess surface comprising etch residue having a different chemical composition than the low-k dielectric layer.

10. The process of claim 8, wherein etching the recess comprises etching the via through the low-k dielectric layer.

11. The process of claim 10, wherein the base substrate comprises an embedded electrical contact disposed therein, and wherein the via is etched through the low-k dielectric layer over the embedded electrical contact disposed in the base substrate to expose a surface of the embedded electrical contact in the via as a portion of the recess surface.

12. The process of claim 11, wherein the annealing environment comprises a reducing gas and wherein annealing is conducted in the annealing environment comprising the reducing gas.

13. The process of claim 1, further comprising depositing a barrier material in the recess after annealing and prior to depositing the electrically-conductive material in the recess to form a barrier layer in the recess, wherein the barrier material is different from the electrically-conductive material.

14. The process of claim 13, further comprising forming a capping layer over the embedded electrical interconnect and the barrier layer.

15. A process for forming an integrated circuit, said process comprising:
forming a low-k dielectric layer overlying a base substrate;
patterning an etch mask over the low-k dielectric layer;
etching a recess into the low-k dielectric layer through the etch mask to expose a recess surface within the recess;
introducing the base substrate having the low-k dielectric layer thereon into an annealing furnace after etching the recess, wherein the annealing furnace provides an annealing environment with the recess surface exposed to the annealing environment; and
depositing an electrically-conductive material in the recess after annealing to form an embedded electrical interconnect.

16. The process of claim 15, wherein the annealing environment has a temperature of at least about 100° C. and wherein the base substrate having the low-k dielectric layer thereon is introduced into the annealing environment that has the temperature of at least about 100° C.

17. The process of claim 15, wherein the annealing environment comprises a gas chosen from inert gas or reducing gas and wherein the base substrate having the low-k dielectric layer thereon is introduced into the annealing environment comprising the gas.

18. The process of claim 17, wherein the annealing environment is free from plasma and wherein the base substrate having the low-k dielectric layer thereon is introduced into the annealing environment comprising the gas and free from plasma.

19. The process of claim 15, wherein the low-k dielectric layer is further defined as a porous low-k dielectric layer comprising a carbon-doped silicon oxide, and wherein the recess is etched into the carbon-doped silicon oxide layer.

20. A process for forming an integrated circuit, said process comprising:
forming a dielectric layer overlying a base substrate;
patterning an etch mask over the dielectric layer;
etching a recess into the dielectric layer through the etch mask to expose a recess surface within the recess;
introducing the base substrate having the dielectric layer thereon into an annealing furnace after etching the recess, wherein the annealing furnace provides an annealing environment with the recess surface exposed to the annealing environment; and
forming at least one overlying layer over the dielectric layer after annealing;
removing portions of the at least one overlying layer from a surface of the dielectric layer outside of the recess to form an embedded feature within the recess.
